(19) United States
(12) Patent Application Publication
(10) Pub. No.: US 2024/0389310 A1
(43) Pub. Date: Nov. 21, 2024

(54) SEMICONDUCTOR MEMORY DEVICES WITH DIELECTRIC FIN STRUCTURES

(71) Applicant: Taiwan Semiconductor Manufacturing Company, Ltd., Hsinchu (TW)

(72) Inventors: Meng-Sheng Chang, Chubei City (TW); Chia-En Huang, Xinfeng Township (TW); Chun Chung Su, New Taipei City (TW); Chih-Ching Wang, Jinhu Township (TW)

(73) Assignee: Taiwan Semiconductor Manufacturing Company, Ltd., Hsinchu (TW)

(21) Appl. No.: 18/784,553

(22) Filed: Jul. 25, 2024

Related U.S. Application Data
(62) Division of application No. 17/473,657, filed on Sep. 13, 2021.
(60) Provisional application No. 63/185,523, filed on May 7, 2021.

(51) Int. Cl. H10B 20/20; H01L 21/02; H01L 29/06; H01L 29/423; H01L 29/66; H01L 29/786

(52) U.S. Cl. CPC H10B 20/20; H01L 21/0259; H01L 29/0665; H01L 29/42392; H01L 29/66545; H01L 29/66553; H01L 29/66742; H01L 29/78696

(57) ABSTRACT

A method of fabricating a memory device includes forming a plurality of first nanostructures, a plurality of second nanostructures, a plurality of third nanostructures, and a plurality of fourth nanostructures; separating the plurality of first nanostructures and the plurality of second nanostructures with a dielectric fin structure; forming a first gate structure wrapping around each of the first nanostructures except for a sidewall that is in contact with the dielectric fin structure; forming a second gate structure wrapping around each of the second nanostructures except for a sidewall that is in contact with the dielectric fin structure; and forming a first interconnect structure coupled to one of the first gate structure or second gate structure. The dielectric structure also extends along the first lateral direction. The first and second gate structures extend along a second lateral direction perpendicular to the first lateral direction.

### CROSS-REFERENCE TO RELATED APPLICATION

This application is a divisional of U.S. Utility application Ser. No. 17/473,657, filed Sep. 13, 2021, which claims priority to and the benefit of U.S. Provisional Application No. 63/185,523, filed May 7, 2021, entitled “A NOVEL ANTI-FUSE STRUCTURE WITH FORK-NANOSHEET PROCESS,” both of which are incorporated herein by reference in their entireties for all purposes.

### BACKGROUND

Integrated circuits (ICs) sometimes include one-time-programmable (OTP) memories to provide non-volatile memory (NVM) in which data are not lost when the IC is powered off. One type of the OTP devices includes anti-fuse memories. The anti-fuse memories include a number of anti-fuse memory cells (or bit cells), whose terminals are disconnected before programming, and are shorted (e.g., connected) after the programming. The anti-fuse memories may be based on metal-oxide-semiconductor (MOS) technology. For example, an anti-fuse memory cell may include a programming MOS transistor (or MOS capacitor) and at least one reading MOS transistor coupled in series. A gate dielectric of the programming MOS transistor may be broken down to cause the gate and the source or drain of the programming MOS transistor to be interconnected. Depending on whether the gate dielectric of the programming MOS transistor is broken down, different data bits can be presented by the anti-fuse memory cell through reading a resultant current flowing through the programming MOS transistor and reading MOS transistor. The anti-fuse memories have the advantageous features of reverse-engineering proofing, since the programming states of the anti-fuse cells cannot be determined through reverse engineering.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a block diagram of an example memory device, in accordance with some embodiments.

FIG. 1B illustrates an example circuit diagram of a portion of the memory device of FIG. 1A, in accordance with some embodiments.

FIG. 2 illustrates an example circuit diagram of a memory cell of the memory device of FIGS. 1A-B, in accordance with some embodiments.

FIG. 3A illustrates an example layout to fabricate the memory cell of FIG. 2, in accordance with some embodiments.

FIG. 3B illustrates another example layout to fabricate the memory cell of FIG. 2, in accordance with some embodiments.

FIGS. 4A, 4B, and 4C illustrates various cross-sectional views of a memory device formed based on the layout of FIG. 3A, in accordance with some embodiments.

FIG. 5 illustrates a flow chart of a method to fabricate the memory device of FIGS. 4A-C, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, cells of an anti-fuse memory are formed as an array. The array includes a number of rows and a number of columns, with at least one cell disposed at an intersection of one of the rows and one of the columns. Each cell can be accessed through a respective combination of a first access line disposed along the corresponding row (e.g., a word line (WL)) and a second access line disposed along the corresponding column (e.g., a bit line (BL)). With such an array configuration, programming transistors of a number of cells may share one of the WLs, while their reading transistors coupled to different BLs, respectively.

As technology node continues to shrink, each cell can be constituted by more than one programming transistor and more than one reading transistor, so as to increase an overall performance of the cell (e.g., increasing its ON current). For example, an anti-fuse cell can have two programming transistors that share a programming WL, and two reading transistors, serially coupled to the programming transistors, that share a reading WL. With this multiple-programming/reading-transistor configuration, an additional gate leakage through one of the programming transistors is present. This is because typically one of the programming transistors is configured to be broken down to successfully program the cell. The other programming transistor can thus provide such a leakage path when programming the cell, which may require a higher level of programming voltage applied on the cell. As such, performance and lifetime of the antifuse memory, as a whole, can be negatively affected. Thus, the exiting anti-fuse memory has not been entirely satisfactory in many aspects.

The present disclosure provides various embodiments of an anti-fuse memory device including a number of anti-fuse memory cells, each of which includes a number of programming transistors and a number of reading transistors. In some embodiments, each of the programing/reading transistors is configured in a nanostructure transistor configuration. For example, each of the programing/reading transistors may be formed based on a gate-all-around (GAA) transistor configuration. Each of the programing/reading transistors can have a channel constituted by a number of nanostructures (e.g., nanosheets, nanobridges, nanowires, etc.), and a gate structure at least partially wrapping around each of the nanostructures. Further, the respective gate structures of the programming transistors of each cell may be (e.g., physically and electrically) isolated from each other with a dielectric fin structure, in accordance with various embodiments. By isolating the gate structures of the programming transistors from each other, the possible leakage path (e.g., one of the programming transistors) can be advantageously eliminated. As such, the issues identified in the existing anti-fuse memories can be avoided in the disclosed anti-fuse memory device.

In addition, the dielectric fin structure can isolate respective channels of the reading transistors, in one embodiment. With the reading transistors formed in such a configuration, advantageously, an area of each memory cell can be significantly decreased, which allows more of the memory cells to be formed in a given real estate of an integrated circuit. Conventionally, the channels of reading transistors are typically formed in respective different active regions, which are required to be separated apart with a minimum spacing, given various design rule limitations. As such, existing anti-fuse memory cell fabricated using the conventional techniques can occupy a significantly greater amount of real estate than the disclosed anti-fuse memory cells, which can make it challenging to integrate the existing anti-fuse memory cells into an integrated circuit that continues to evolve with advanced technologies.

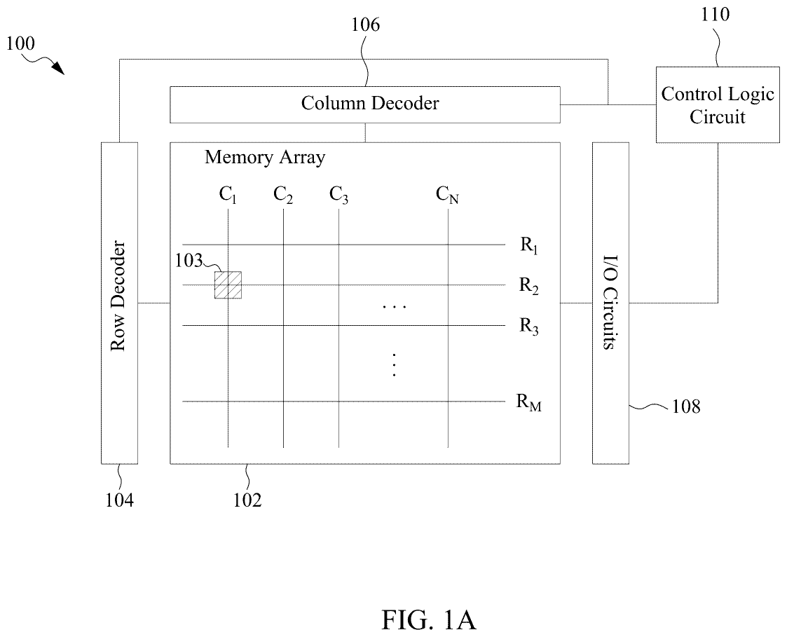

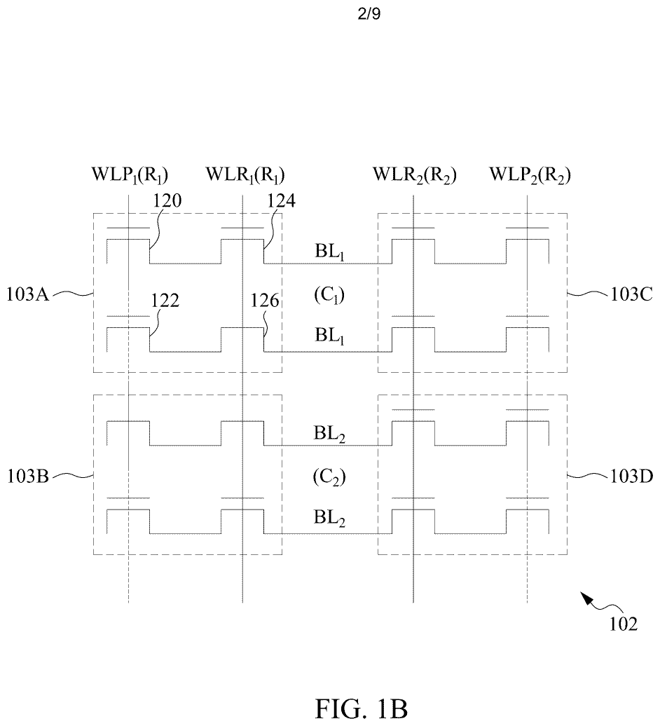

FIG. 1A illustrates a memory device 100, in accordance with various embodiments. In the illustrated embodiment of FIG. 1A, the memory device 100 includes a memory array 102, a row decoder 104, a column decoder 106, an input/output (I/O) circuit 108, and a control logic circuit 110. Despite not being shown in FIG. 1A, all of the components of the memory device 100 may be operatively coupled to each other and to the control logic circuit 112. Although, in the illustrated embodiment of FIG. 1A, each component is shown as a separate block for the purpose of clear illustration, in some other embodiments, some or all of the components shown in FIG. 1A may be integrated together. For example, the memory array 102 may include an embedded I/O circuit 108.

The memory array 102 is a hardware component that stores data. In one aspect, the memory array 102 is embodied as a semiconductor memory device. The memory array 102 includes a plurality of memory cells (or otherwise storage units) 103. The memory array 102 includes a number of rows R₁, R₂, R₃ . . . R_{M}, each extending in a first direction (e.g., X-direction) and a number of columns C₁, C₂, C₃ . . . C_{N}, each extending in a second direction (e.g., Y-direction). Each of the rows/columns may include one or more conductive structures each configured as an access line (e.g., a programming word line (WLP), a reading word line (WLR), a bit line (BL)), which will be discussed below. In some embodiments, each memory cell 103 is arranged in the intersection of a corresponding row and a corresponding column and can be operated according to voltages or currents through the respective conductive structures of the column and row.

In some aspects of the present disclosure, each memory cell 103 is implemented as an anti-fuse memory cell that includes a first set of transistors and a second set of transistors coupled in series. The first set of transistors can each function as a programming transistor of the memory cell, and the second sets of transistors can each function as a reading transistor of the memory cell. At least one of the first set of transistors, which are isolated from each other with a dielectric fin structure, can be gated by a WLP; and the second set of transistors, which may or may not be isolated from each other with a dielectric fin structure, can be gated by a WLR, which will be discussed below. Although the present disclosure is directed to implementing the memory cell 103 as an anti-fuse memory cell, it should be understood that the memory cell 103 can include any of various other memory cells, while remaining within the scope of present disclosure.

The row decoder 104 is a hardware component that can receive a row address of the memory array 102 and assert a conductive structure (e.g., a word line) at that row address. The column decoder 106 is a hardware component that can receive a column address of the memory array 102 and assert one or more conductive structures (e.g., a bit line, a source line) at that column address. The I/O circuit 108 is a hardware component that can access (e.g., read, program) each of the memory cells 103 asserted through the row decoder 104 and column decoder 106. The control logic circuit 110 is a hardware component that can control the coupled components (e.g., 102 through 108).

FIG. 1B illustrates an example circuit diagram of a portion of the memory device 100 (e.g., some of the memory cells 103), in accordance with some embodiments. In the illustrated example of FIG. 1B, anti-fuse memory cells 130A, 130B, 130C, and 130D of the memory array 102 are shown. Although four anti-fuse memory cells 103A-D are shown, it should be appreciated that the memory array 102 can have any number of anti-fuse memory cells, while remaining within the scope of present disclosure.

As mentioned above, the memory cells 103 can be arranged as an array. In FIG. 1B, the memory cells 103A and 103B may be disposed in a same row but in respectively different columns; and the memory cells 103C and 103D may be disposed in a same row but in respectively different columns. For example, the memory cells 103A and 103B are disposed in row R₁, but in columns C₁ and C₂, respectively; and the memory cells 103C and 103D are disposed in row R₂, but in columns C₁ and C₂, respectively. With such a configuration, each of the memory cells can be operatively coupled to the access lines in the corresponding row and column, respectively.

For example in FIG. 1B, the memory cell 103A is operatively coupled to a programming word line and a reading word line in row R₁ (hereinafter WLP1 and WLR1, respectively) and to a bit line in column C₁ (hereinafter BL1); the memory cell 103B is operatively coupled to the WLP1 and WLR1 in row R₁ and to a bit line in column C₂ (hereinafter BL2); the memory cell 103C is operatively coupled to a programming word line and a reading word line in row R₂ (hereinafter WLP2 and WLR2, respectively) and to the BL1 in column C₁; and the memory cell 103D is operatively coupled to the WLP2 and WLR2 in row R₂ and to the BL2 in column C₂.

In some embodiments, each of the memory cells 103A-D can be operatively coupled to the I/O circuit 108 through the respective WLR, WLP, and BL for being accessed (e.g., programmed, read). For example, the I/O circuit 108 can cause the row decoder 104 to assert the WLP1 and WLR1 and the column decoder 106 to assert the BL1, so as to access the memory cell 103A through the WLP1, WLR1, and BL1. Accordingly, each of the memory cells 103A-D can be individually selected to be programmed or read. Details of programming and reading the memory cell will be discussed in further detail below.

Each of the memory cells 103A to 103D includes a number of programming transistors and a number of reading transistors, wherein each of the programming transistors is coupled to a corresponding one of the reading transistors in series. Further, at least two of the programming transistors are separately gated, while the reading transistors may be commonly gated, in accordance with various embodiments. The memory cell 103A is selected as a representative example in the following discussions.

As shown in FIG. 1B, the memory cell 103A includes programming transistors 120 and 122, and the reading transistors 124 and 126. The programming transistor 120 is coupled to the reading transistor 124 in series; and the programming transistor 122 is coupled to the reading transistor 126 in series. One source/drain terminal of each of the programming transistors 120 and 122 are floating (i.e., not connected to any other functioning features); and the other source/drain terminal of each of the programming transistors 120 and 122 is serially coupled to one source/drain terminal of the corresponding reading transistor 124/126, with the other source/drain terminals of the reading transistors 124 and 126 commonly coupled to the BL1.

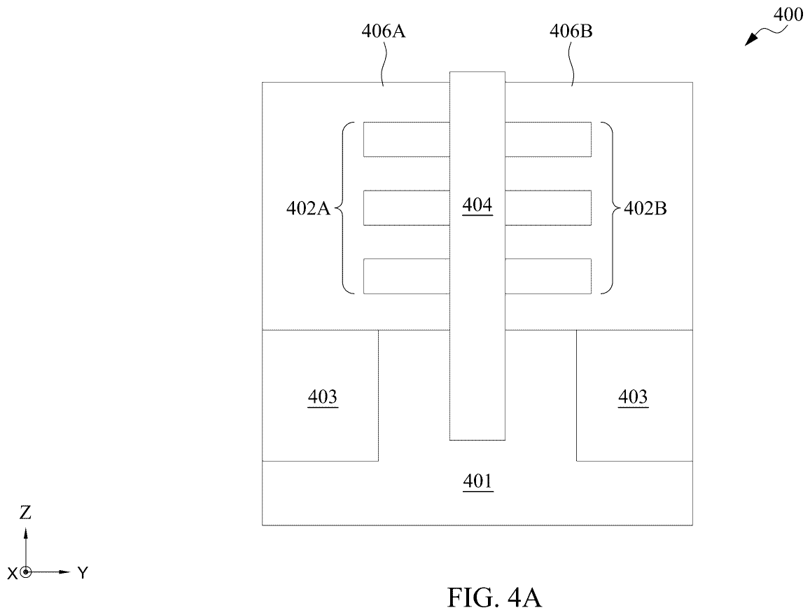

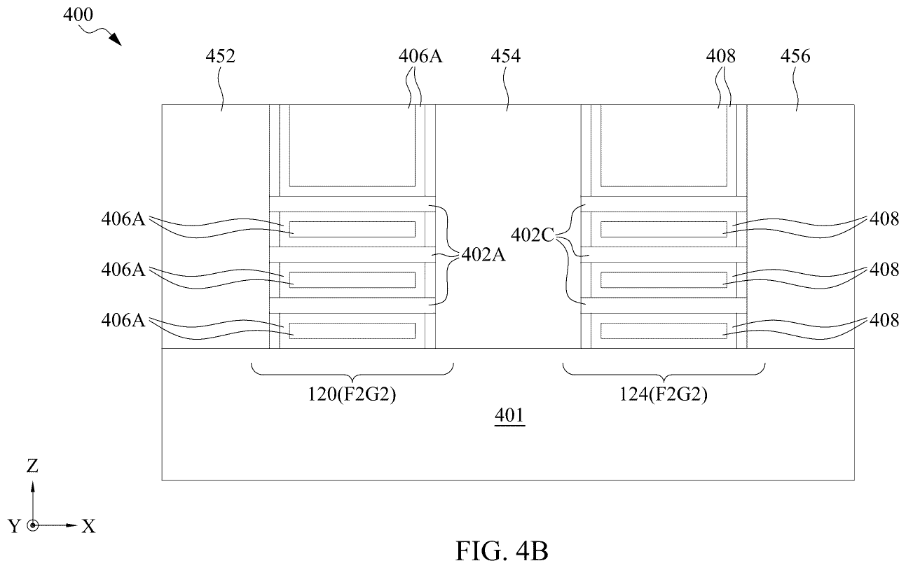

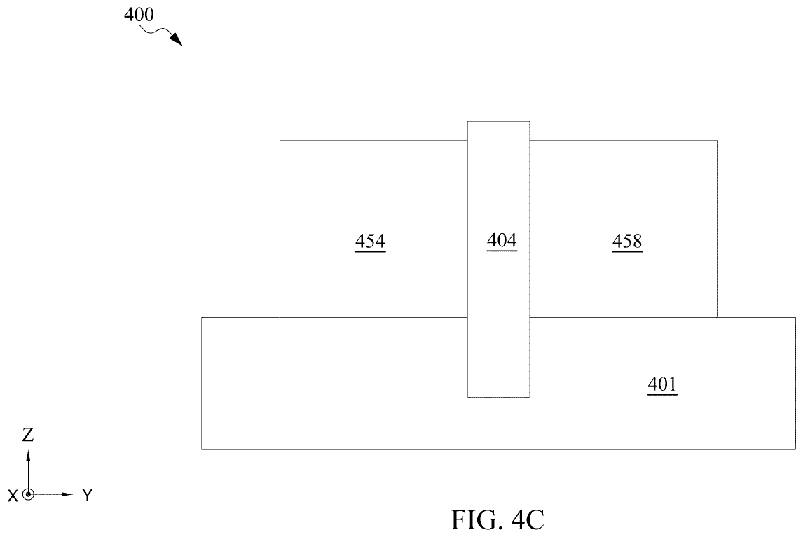

Further, the programming transistor 120 is gated by the WLP1 (i.e., a gate terminal of the programming transistor 120 is coupled to the WLP1), while a gate terminal of the programming transistor 122 may not be coupled to (or otherwise disconnected from) the WLP1. On the other hand, the reading transistors 124 and 126 are both gated by the WLR1 (i.e., both gate terminals of the reading transistors 124 and 126 are coupled to the WLR1). According to various embodiment of present disclosure, the gate terminals (formed as gate structures as discussed below) of the programming transistors 120 and 122 may be isolated from each other by forming a dielectric fin structure interposed between the gate structures. Such a dielectric fin structure can also isolate channel structures of the programming transistors 120 and 122, thereby causing the perimeter of each channel structure to be wrapped by the corresponding gate structure except for one of the sidewalls in contact with (or otherwise disposed immediately next to) the dielectric fin structure. Details of the disclosed dielectric fin structure will be discussed below with respect to FIGS. 4A-C.

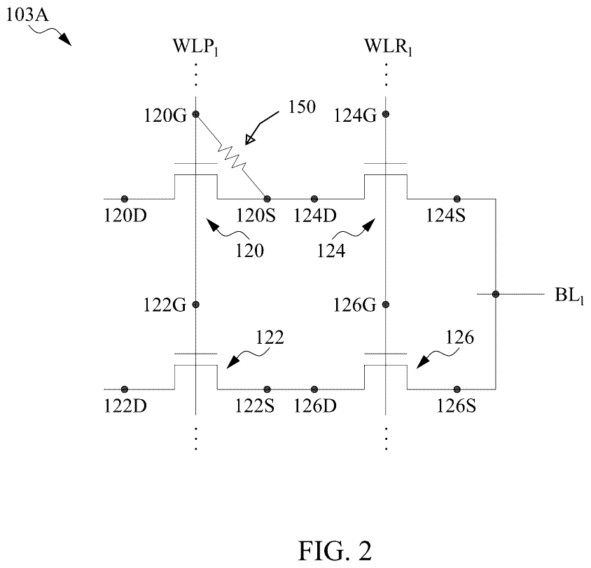

Referring to FIG. 2, provided is a further detailed circuit diagram of the memory cell 103A to illustrate operations of each of the memory cells 103, in accordance with some embodiments. As shown, each of the programming/reading transistors, 120 to 126, may include an n-type metal-oxide-semiconductor field-effect-transistor (n-type MOSFET) or sometimes referred to as an NMOS transistor. However, it should be understood that each of the programming/reading transistors, 120 to 126, may include a p-type metal-oxide-semiconductor field-effect-transistor (p-type MOSFET), while remaining within the scope of present disclosure.

Specifically, the programming transistors 120 and 122 have their respective drain terminals 120D and 122D floating (e.g., coupled to nothing functional), and their respective source terminals 120S and 122S coupled to drain terminals of the reading transistors 124 and 126, 124D and 126D, respectively. Source terminals of the reading transistors 124 and 126, 124S and 126S, are commonly coupled to the BL1. The programming transistor 120 has a gate terminal 120G coupled to the WLP1, while the programming transistor 122 has a gate terminal 122G isolated from the WLP1. On the other hand, the reading transistors 124 and 126 have their respective gate terminals, 124G and 126G, commonly coupled to the WLR1.

To program the memory cell 103A, the reading transistors 124 and 126 are turned on by supplying a high enough voltage (e.g., a positive voltage corresponding to a logic high state) to the gate terminals 124G and 126G via the WLR1. Prior to, concurrently with or subsequently to the reading transistors 124 and 126 being turned on, a sufficiently high voltage (e.g., a breakdown voltage (V_{BD}) which is sometimes referred to as a programming voltage) is applied to the WLP1, and a low enough voltage (e.g., a positive voltage or ground voltage corresponding to a logic low state) is applied to the BL1. The low voltage (applied on the BL1) can be passed to the source terminal 120S such that V_{BD} will be present across the source terminal 120S and the gate terminal 120G thereby causing a breakdown of a portion of a gate dielectric (e.g., the portion between the source terminal 120S and the gate terminal 120G) of the programming transistor 120. As the gate terminal 122G of the programming transistor 122 is disconnected from the WLP1, the WLP1 is immune from any leakage current that may be induced through the gate terminal 122G. Thus, any unnecessary IR drop on the WLP1 can be significantly reduced. Stated alternatively, the applied V_{BD} may be fully across the gate and source terminals of the programming transistor 120. In turn, the memory cell 103A can be more efficiently programmed.

After the gate dielectric of the programming transistor 120 is broken down, a behavior of the portion of the gate dielectric interconnecting the gate terminal 120G and the source terminal 120S is equivalently resistive. For example, such a portion may function as a resistor 150, as shown in FIG. 2. Before the programming (before the gate dielectric of the programming transistor 120 is broken down), no conduction path exists between the BL1 and the WLP1, even if the reading transistors 124 and 126 are turned on. After the programming, a conduction path exists between the BL1 and the WLP1 (e.g., via the resistor 150), when the reading transistors 124 and 126 are turned on.

To read the memory cell 103A, similarly to the programming, the reading transistors 124 and 126 are turned on via the WLR1, and the BL1 is coupled to a voltage corresponding to the logic low state. In response, a positive voltage is applied to the gate terminal of the programming transistor 120 through the WLP1. As discussed above, if the gate dielectric of the programming transistor 120 is not broken down, no conduction path exists between the BL1 and the WLP1. Thus, a relatively low current conducts from the WLP1, through the transistors 120 and both transistors 124 and 126, and to the BL1. If the gate dielectric of the programming transistor 120 is broken down, a conduction path exists between the BL1 and the WLP1. Thus, a relatively high current conducts from the WLP1, through the transistor 120 (now equivalent to the resistor 150) and both transistor 124 and 126, and to the BL1. Such a low current and high current may sometimes be referred to as I_{off} and Iₒₙ of the memory cell 130A, respectively. A circuit component (e.g., a sense amplifier) of the I/O circuit 108 (FIG. 1), coupled to the BL1 can differentiate I_{off} from Iₒₙ (or vice versa), and thus determine whether the memory cell 130A presents a logic high (“1”) or a logic low (“0”). For example, when Iₒₙ is read, the memory cell 103A may present 1; and when I_{off} is read, the memory cell 103A may present 0.

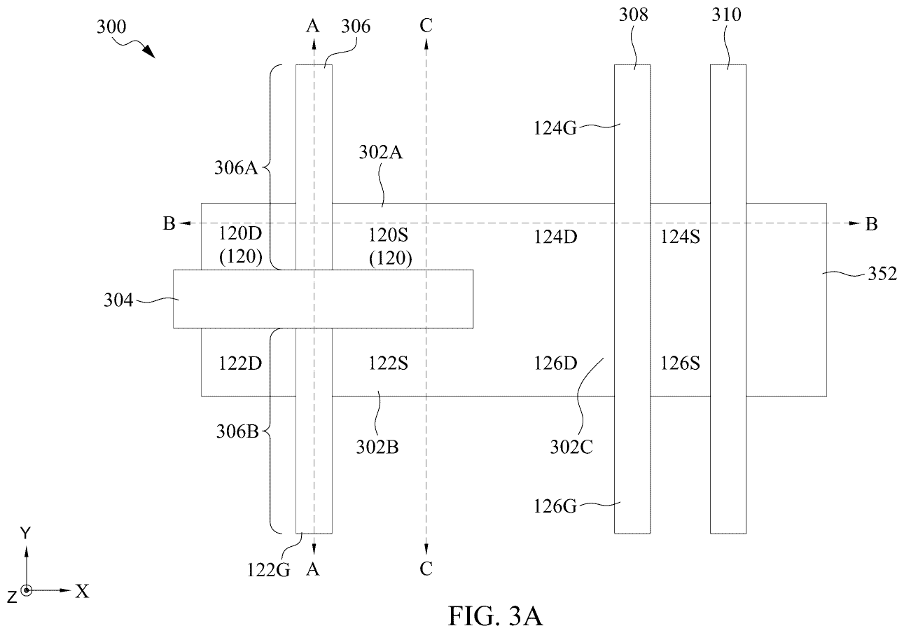

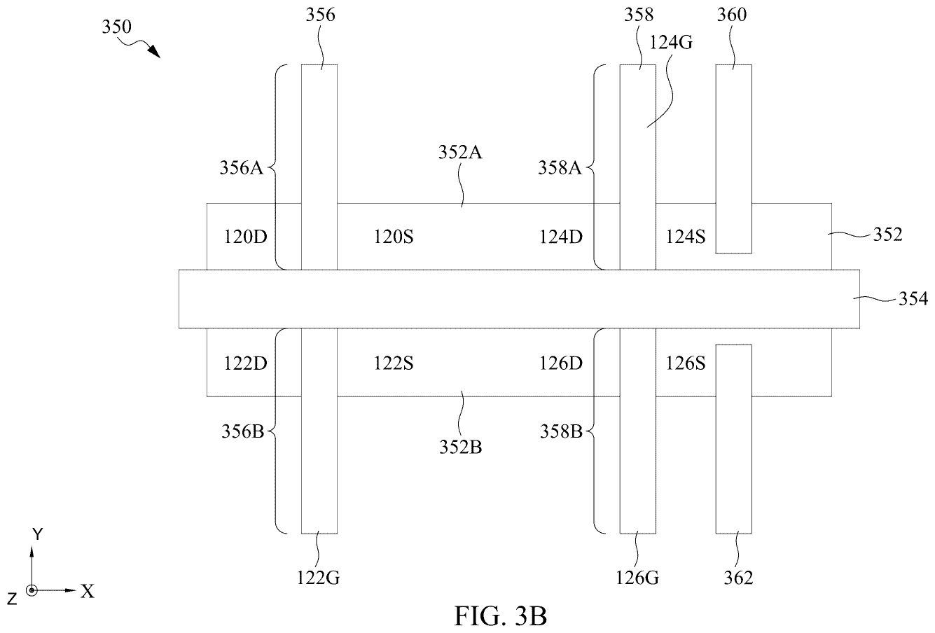

FIG. 3A illustrates an example layout 300 of one of the disclosed anti-fuse memory cells (e.g., 103A), in accordance with various embodiments. As shown, the layout 300 includes pattern 302 that is configured to form an active region (hereinafter “active region 302”); pattern 304 that is configured to form a dielectric fin structure (hereinafter “dielectric fin structure 304”); patterns 306 and 308 that are each configured to form a gate structure (hereinafter “gate structure 306” and “gate structure 308,” respectively); and pattern 310 that is configured to form an interconnect structure, e.g., MD, (hereinafter “MD 310”).

The active region 302 may extend along a first lateral direction (e.g., X-direction) and the dielectric fin structure 304 may also extend along the same direction, while the gate structures 306 and 308 and MD 310 may extend along a second, different lateral direction (e.g., Y-direction). Further, the dielectric fin structure 304 partially extends across the active region 302, thereby separating a portion of the active region 302 into two portions along the Y-direction. Stated another way, the dielectric fin structure 304 may extend along the X-direction with a length that is shorter than a length with which the active region 302 extends along the same direction, and the dielectric fin structure 304 is disposed closer to one end of the active region 302 than the other end of the active region 302. For example in FIG. 3A, the dielectric fin structure 304 separates a left portion of the active region 302 into two portions, 302A and 302B, while a right portion of the active region 302 may remain as a single piece, 302C. Still further, the dielectric fin structure 304 can separate the gate structure 306 into a number of portions, while the gate structure 308 (and MD 310) may remain as a single piece. For example, the dielectric fin structure 304 separates the gate structure 306 into portions 306A and 306B.

According to various embodiments, a layout used to fabricate an anti-fuse memory array may include a number of the layouts similar as 300 that are repeatedly arranged along the X-direction and Y-direction. However, it should be understood that such an array layout can include any number of each of the active regions, dielectric fin structures, and gate structures, while remaining within the scope of present disclosure. For example, the array layout does not necessarily have the same number of dielectric fin structures as the number of active regions, i.e., one or more of the active regions may not be separated by a dielectric fin structure.

According to embodiments, the active region 302 is formed of a stack structure protruding from a major surface of a substrate. The stack includes a number of semiconductor nanostructures (e.g., nanosheets) extending along the X-direction and vertically separated from each other. Portions of the semiconductor structures in the stack that are overlaid by the gate structures 306 and 308 remain, while other portions are replaced with a number of epitaxial structures.

The remaining portions of the semiconductor structures can be configured as the channel of a corresponding transistor, the epitaxial structures coupled to both sides (or ends) of the remaining portions of the semiconductor structures can be configured as source/drain structures (or terminals) of the transistor, and a portion of the gate structure that overlays (e.g., straddles) the remaining portions of the semiconductor structures can be configured as a gate structures (or terminal) of the transistor.

For example in FIG. 3A, a portion of the active region portion 302A that is overlaid by the gate structure portion 306A may include a number of nanostructures vertically separated from each other, which can function as a channel of the programming transistor 120 (FIG. 2). Portions of the active region portion 302A that are disposed on opposite sides of the gate structure portion 306A are replaced with epitaxial structures. Such epitaxial structures can function as the source/drain terminals 120D and 120S of the programming transistor 120 (FIG. 2), respectively. The gate structure portion 306A can function as the gate terminal 120G of the programming transistor 120 (FIG. 2).

A portion of the active region portion 302B that is overlaid by the gate structure portion 306B may include a number of nanostructures vertically separated from each other, which can function as a channel of the programming transistor 122 (FIG. 2). Portions of the active region portion 302B that are disposed on opposite sides of the gate structure portion 306B are replaced with epitaxial structures. Such epitaxial structures can function as the source/drain terminals 122D and 122S of the programming transistor 122 (FIG. 2), respectively. The gate structure portion 306B can function as the gate terminal 122G of the programming transistor 122 (FIG. 2).

A portion of the active region 302C that is overlaid by the gate structure 308 may include a number of nanostructures vertically separated from each other, which can function as a channel of the reading transistor 124 and a channel of the reading transistor 126 (FIG. 2). Portions of the active region 302C that are disposed on opposite sides of the gate structure 308 are replaced with epitaxial structures. Such epitaxial structures can function as the source/drain terminals 124D/126D and 124S/126S of the reading transistors 124/126 (FIG. 2), respectively. The gate structure 308 can function as the gate terminal 124G of the reading transistor 124 and the gate terminal 126G of the reading transistor 126 (FIG. 2), respectively.

Further, the dielectric fin structure 304 is formed to also protrude from the major surface of the substrate. Such a dielectric fin structure extends along a sidewall of the stack structure (extending along the X-direction) formed based on the active region 302, and thus, one sidewall of each semiconductor nanostructure of the transistor channel (facing away or toward Y-direction) is in contact with the dielectric fin structure. Using the transistor 120 as an example, while being overlaid by the gate terminal 120G, each of the nanostructures of the channel has a sidewall in contact with the dielectric fin structure 304. Specifically, each of the nanostructures has a top surface, a bottom surface, and four sidewalls. The top and bottom surfaces are wrapped by the gate terminal 120G. Two of the sidewalls facing the X-direction are coupled to the source/drain terminals 120D and 120S, respectively, one of the sidewalls facing away from the dielectric fin structure 304 is wrapped by the gate terminal 120G, and one of the sidewalls facing toward the dielectric fin structure 304 is in contact with the dielectric fin structure 304, which will be discussed in further detail with respect to FIGS. 4A-C.

Corresponding to the circuit diagram shown in FIG. 2, the gate terminal 120G is coupled to a programming word line (e.g., WLP1), while the gate terminal 122G is disconnected from the WLP1 with the dielectric fin structure 304. The drain terminals 120D and 122D are floating. The source terminal 120S is connected to the drain terminal 124D, and the source terminal 122S is connected to the drain terminal 126D. The gate terminals 124G and 126G are both coupled to a reading word line (e.g., WLR1). The source terminals 124S and 126S are coupled to a bit line (e.g., BL1). In some embodiments, the MD 310 may function as the BL1.

FIG. 3B illustrates another example layout 350 of one of the disclosed anti-fuse memory cells (e.g., 103A), in accordance with various embodiments. As shown, the layout 350 includes pattern 352 that is configured to form an active region (hereinafter “active region 352”); pattern 354 that is configured to form a dielectric fin structure (hereinafter “dielectric fin structure 354”); patterns 356 and 358 that are each configured to form a gate structure (hereinafter “gate structure 356” and “gate structure 358,” respectively); and pattern 360 and 362 that are each configured to form an interconnect structure, e.g., MD, (hereinafter “MD 360” and “MD 362,” respectively).

The active region 352 may extend along a first lateral direction (e.g., X-direction) and the dielectric fin structure 354 may also extend along the same direction, while the gate structures 356 and 358 and MDs 360 and 362 may extend along a second, different lateral direction (e.g., Y-direction). Further, the dielectric fin structure 354 fully extends across the active region 352, thereby separating the active region 352 into two portions along the Y-direction. Stated another way, the dielectric fin structure 354 may extend along the X-direction with a length that is longer than or about equal to a length with which the active region 352 extends along the same direction. For example in FIG. 3B, the dielectric fin structure 354 separates the active region 352 into two portions 352A and 352B. Still further, the dielectric fin structure 354 can separate the gate structure 356 into a number of portions, 356A and 356B, and separate the gate structure 358 into a number of portions, 358A and 358B.

According to various embodiments, a layout used to fabricate an anti-fuse memory array may include a number of the layouts similar as 350 that are repeatedly arranged along the X-direction and Y-direction. However, it should be understood that such an array layout can include any number of each of the active regions, dielectric fin structures, and gate structures, while remaining within the scope of present disclosure. For example, the array layout does not necessarily have the same number of dielectric fin structures as the number of active regions, i.e., one or more of the active regions may not be separated by a dielectric fin structure.

According to embodiments, the active region 352 is formed of a stack structure protruding from a major surface of a substrate. The stack includes a number of semiconductor nanostructures (e.g., nanosheets) extending along the X-direction and vertically separated from each other. Portions of the semiconductor structures in the stack that are overlaid by the gate structures 356 and 358 remain, while other portions are replaced with a number of epitaxial structures.

The remaining portions of the semiconductor structures can be configured as the channel of a corresponding transistor, the epitaxial structures coupled to both sides (or ends) of the remaining portions of the semiconductor structures can be configured as source/drain structures (or terminals) of the transistor, and a portion of the gate structure that overlays (e.g., straddles) the remaining portions of the semiconductor structures can be configured as a gate structures (or terminal) of the transistor.

For example in FIG. 3B, a portion of the active region portion 352A that is overlaid by the gate structure portion 356A may include a number of nanostructures vertically separated from each other, which can function as a channel of the programming transistor 120 (FIG. 2). Portions of the active region portion 352A that are disposed on opposite sides of the gate structure portion 356A are replaced with epitaxial structures. Such epitaxial structures can function as the source/drain terminals 120D and 120S of the programming transistor 120 (FIG. 2), respectively. The gate structure portion 356A can function as the gate terminal 120G of the programming transistor 120 (FIG. 2).

A portion of the active region portion 352B that is overlaid by the gate structure portion 356B may include a number of nanostructures vertically separated from each other, which can function as a channel of the programming transistor 122 (FIG. 2). Portions of the active region portion 352B that are disposed on opposite sides of the gate structure portion 356B are replaced with epitaxial structures. Such epitaxial structures can function as the source/drain terminals 122D and 122S of the programming transistor 122 (FIG. 2), respectively. The gate structure portion 356B can function as the gate terminal 122G of the programming transistor 122 (FIG. 2).

A portion of the active region portion 352A that is overlaid by the gate structure portion 358A may include a number of nanostructures vertically separated from each other, which can function as a channel of the reading transistor 124 (FIG. 2). Portions of the active region portion 352A that are disposed on opposite sides of the gate structure portion 358A are replaced with epitaxial structures. Such epitaxial structures can function as the source/drain terminals 124D and 124S of the reading transistor 124 (FIG. 2), respectively. The gate structure portion 358A can function as the gate terminal 124G of the reading transistor 124 (FIG. 2).

A portion of the active region portion 352B that is overlaid by the gate structure portion 358B may include a number of nanostructures vertically separated from each other, which can function as a channel of the reading transistor 126 (FIG. 2). Portions of the active region portion 352B that are disposed on opposite sides of the gate structure portion 358B are replaced with epitaxial structures. Such epitaxial structures can function as the source/drain terminals 126D and 126S of the reading transistor 126 (FIG. 2), respectively. The gate structure portion 358B can function as the gate terminal 126G of the reading transistor 126 (FIG. 2).

Further, the dielectric fin structure 304 is formed to also protrude from the major surface of the substrate. Such a dielectric fin structure extends along a sidewall of the stack structure (extending along the X-direction) formed based on the active region portions 352A and 352B, and thus, one sidewall of each semiconductor nanostructure of the transistor channel (facing away or toward Y-direction) is in contact with the dielectric fin structure. Using the transistor 120 as an example, while being overlaid by the gate terminal 120G, each of the nanostructures of the channel has a sidewall in contact with the dielectric fin structure 354. Specifically, each of the nanostructures has a top surface, a bottom surface, and four sidewalls. The top and bottom surfaces are wrapped by the gate terminal 120G. Two of the sidewalls facing the X-direction are coupled to the source/drain terminals 120D and 120S, respectively, one of the sidewalls facing away from the dielectric fin structure 354 is wrapped by the gate terminal 120G, and one of the sidewalls facing toward the dielectric fin structure 354 is in contact with the dielectric fin structure 354, which will be discussed in further detail with respect to FIGS. 4A-C.

Corresponding to the circuit diagram shown in FIG. 2, the gate terminal 120G is coupled to a programming word line (e.g., WLP1), while the gate terminal 122G is disconnected from the WLP1 with the dielectric fin structure 354. The drain terminals 120D and 122D are floating. The source terminal 120S is connected to the drain terminal 124D, and the source terminal 122S is connected to the drain terminal 126D. The gate terminals 124G and 126G are both coupled to a reading word line (e.g., WLR1). The source terminals 124S and 126S are coupled to a bit line (e.g., BL1). In some embodiments, the MD 360 and the MD 362 may be coupled to each other to collectively function as the BL1.

FIGS. 4A, 4B, and 4C illustrate various cross-sectional views of a memory device 400 fabricated based on the layout 300 of FIG. 3A, in accordance with various embodiments. For example, FIG. 4A illustrates the cross-sectional view of a portion of the memory device 400 that is cut along the gate structure portions 306A and 306B (e.g., the lengthwise direction of a gate structure); FIG. 4B illustrates the cross-sectional view of a portion of the memory device 400 that is cut along a portion of the active region 302 (including the active region portion 302A) across the gate structure portion 306A and the gate structure 308 (e.g., the lengthwise direction of an active region); and FIG. 4C illustrates the cross-sectional view of a portion of the memory device 400 that is cut across the portions 302A-B and dielectric structure 304 between the gate structures 306 and 308 (e.g., in parallel with the lengthwise direction of a gate structure).

It should be appreciated that a memory device fabricated based on the layout 350 (FIG. 3B) should be substantially similar to the memory device 400 except that the channels of the reading transistors 124 and 126 (formed based on the layout 350) each have a sidewall in contact with a dielectric fin structure (formed based on 354). Thus, the following discussions will be focused on the memory device 400 formed based on the layout 300 of FIG. 3A.

Referring first to FIG. 4A, the memory device 400 includes a substrate 401 including a number of isolation regions (sometimes referred to as shallow trench isolation (STI) regions) 403 formed over a major surface of the substrate 401. Over the major surface, the memory device 400 includes plural sets of nanostructures, 402A and 402B. Each set includes a number of nanostructures vertically separated from one another, as shown. In some embodiments, such sets of nanostructures 402A to 408B can be fabricated based on the patterns 302A to 308B of the layout 300, respectively. The memory device 400 includes (e.g., metal) gate structures 406A and 406B, which can be fabricated based on the patterns 306A and 306B of the layout 300, respectively. The memory device 400 includes a dielectric fin structure 404, which can be fabricated based on the pattern 304 of the layout 300.

As shown in the cross-sectional view of FIG. 4A, each nanostructure of the sets 402A and 408B has a top surface, a bottom surface, and a first sidewall (facing away or toward the Y-direction) wrapped by a corresponding gate structure, with a second sidewall (facing away or toward the Y-direction) contacting a corresponding dielectric fin structure. As such, two sets of the nanostructures, together with a corresponding dielectric fin structure, may form a fork, according to various embodiments. For example, the sets of nanostructures 402A and 402B, together with the dielectric fin structure 404, may form a fork. Although not shown, it should be appreciated that the memory device 400 can include a number of interconnect structures operatively coupled to respective features. For example, the memory device 400 can include a first via structure (sometimes referred to as “VG”) configured to couple the gate structure 406A to a programming word line (e.g., WLP1 of FIG. 2), while such a programming word line may not be coupled to the gate structure 406B.

Referring next to the cross-sectional view of FIG. 4B, the top surface and bottom surface of each nanostructure of set 402A are shown as being wrapped around by the gate structure 406A, which can include multiple layers, for example, a gate dielectric layer and a gate metal. Epitaxial structures 452 and 454, which respectively replace the portions of active region 302A on opposite sides of the gate structure portion 306A (FIG. 3A), are disposed on (or coupled to) the opposite sides of each nanostructure of set 402A (along the X-direction).

Such features/structures (e.g., the set of nanostructures 402A, gate structure 406A, and epitaxial structures 452 and 454) can operatively function as a first one of the programming transistors (e.g., 120 of FIGS. 2 and 3A). Along the X-direction (e.g., the direction in which the active region 302 extends), the memory device 400 further includes a number of similar features/structures. For example, the memory device 400 includes another set of nanostructures 402C (formed based on the active region portion 302C of FIG. 3A), a gate structure 408 (formed based on the gate structure 308 of FIG. 3A), and another epitaxial structure 456. The set of nanostructures 402C, gate structure 408, and epitaxial structures 454 and 456 can operatively function as a first one of the reading transistors (e.g., 124 of FIGS. 2 and 3A).

In some embodiments, the programming transistor and reading transistor may share the same epitaxial structure, 454 (i.e., coupled in series), with the epitaxial structure 456 functioning as the source terminal of the reading transistor 124 that is coupled to bit line. Accordingly, it should be appreciated that the memory device 400 can include a number of interconnect structures operatively coupled to respective features. For example, the memory device 400 can include a second via structure (sometimes referred to as “MD”) configured to couple the epitaxial structure 454 to a bit line (e.g., BL1 of FIG. 2).

Referring then to the cross-sectional view of FIG. 4C, the dielectric fin structure 404 can further separate respective epitaxial structures of the programming transistors (e.g., along the Y-direction). For example, the dielectric fin structure 404 separates the epitaxial structure 454 of a programing transistor (e.g., 120 formed based on the active region portion 302A of FIG. 3A) from the epitaxial structure 458 of another programming transistor (e.g., 122 formed based on the active region 302B of FIG. 3A).

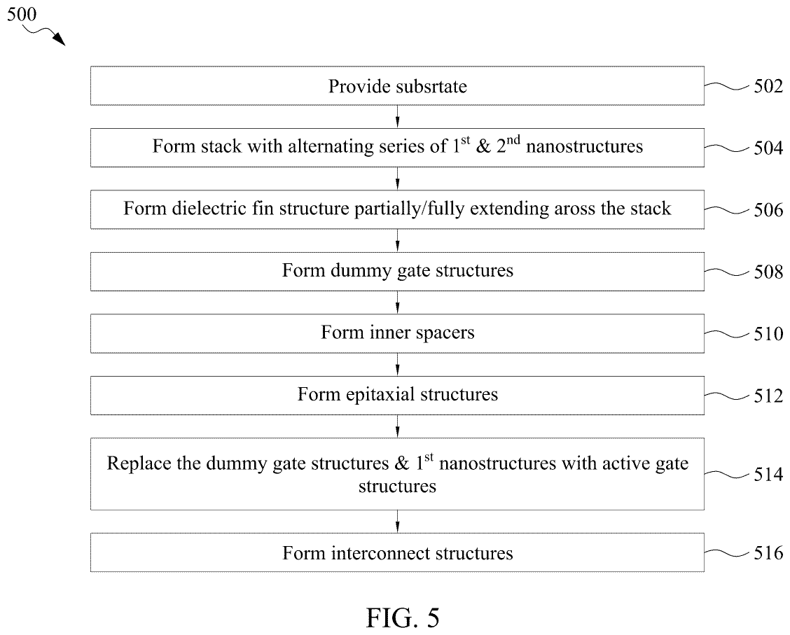

FIG. 5 illustrates a flowchart of a method 500 to form a portion of the above-described memory device 400, according to one or more embodiments of the present disclosure. For example, the method 500 includes operations to fabricate a number of programming transistors (e.g., 120 and 122) of an antifuse cell (e.g., 103A) separated or otherwise isolated from each other with a dielectric fin structure. Thus, the operations of the method 500 may be discussed in conjunction with some of the features of FIGS. 1-4C as a non-limiting example. It is noted that the method 500 is merely an example and is not intended to limit the present disclosure. Accordingly, it is understood that additional operations may be provided before, during, and after the method 500 of FIG. 5, and that some other operations may only be briefly described herein.

The method 500 starts with operation 502 in which a substrate (e.g., 401) is provided, in accordance with various embodiments. The substrate includes a semiconductor material substrate, for example, silicon. Alternatively, the substrate may include other elementary semiconductor material such as, for example, germanium. The substrate may also include a compound semiconductor such as silicon carbide, gallium arsenic, indium arsenide, and indium phosphide. The substrate may include an alloy semiconductor such as silicon germanium, silicon germanium carbide, gallium arsenic phosphide, and gallium indium phosphide. In one embodiment, the substrate includes an epitaxial layer. For example, the substrate may have an epitaxial layer overlying a bulk semiconductor. Furthermore, the substrate may include a semiconductor-on-insulator (SOI) structure. For example, the substrate may include a buried oxide (BOX) layer formed by a process such as separation by implanted oxygen (SIMOX) or other suitable technique, such as wafer bonding and grinding.

The method 500 proceeds to operation 504 in which a stack, including an alternating series of first nanostructures and second nanostructures, is formed, in accordance with various embodiments. Such a stack can be formed based on one of the (active region) patterns discussed with respect to FIGS. 3A-B. In some embodiments, the first nanostructures may include SiGe sacrificial nanostructures (e.g., which will be partially replaced with portions of later formed active gate structures disposed between adjacent ones of nanostructures 402A and between adjacent ones of nanostructures 402B), and the second nanostructures may include Si channel nanostructures (e.g., nanostructures 402A, nanostructures 402B). Such a stack may sometimes be referred to as a superlattice. In a non-limiting example, the SiGe sacrificial nanostructures can be SiGe 25%. The notation “SiGe 25%” is used to indicate that 25% of the SiGe material is Ge. It is understood the percentage of Ge in each of the SiGe sacrificial nanostructures can be any value between 0 and 100 (excluding 0 and 100), while remaining within the scope of present disclosure. In some other embodiments, the second nanostructures may include a first semiconductor material other than Si and the first nanostructures may include a second semiconductor material other than SiGe, as long as the first and second semiconductor materials are respectively characterized with different etching properties (e.g., etching rates).

The alternating series of nanostructures can be formed by epitaxially growing one layer and then the next until the desired number and desired thicknesses of the nanostructures are achieved. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process. Epitaxial silicon, silicon germanium, and/or carbon doped silicon (Si:C) silicon can be doped during deposition (in-situ doped) by adding dopants, n-type dopants (e.g., phosphorus or arsenic) or p-type dopants (e.g., boron or gallium), depending on the type of transistor.

The method 500 proceeds to operation 506 in which a dielectric fin structure (e.g., 404) is formed to partially or fully extend across the stack, in accordance with various embodiments. The partially extending dielectric fin structure can be formed based on the (dielectric fin structure) pattern discussed with respect to FIG. 3A, and the fully extending dielectric fin structure can be formed based on the (dielectric fin structure) pattern discussed with respect to FIG. 3B. By extending along the same lengthwise direction as the stack and being formed around a middle portion of the stack, the dielectric fin structure can separate at least a portion of the stack into two portions that are on opposite sides of the dielectric fin structure along a direction perpendicular to the lengthwise direction of the dielectric fin structure (and the stack).

The dielectric fin structure can be formed by performing at least some of the following operations: etching the stack to form a recess traversing across the stack until a major surface of the substrate is exposed or to a certain depth below the major surface; depositing a dielectric material to at least fill up the recess; and optionally polishing the workpiece to remove the excessive dielectric material. In some embodiments, the dielectric material is formed of an insulation material, such as an isolation dielectric. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used.

The method 500 proceeds to operation 508 in which a number of dummy gate structures (which will be replaced with active gate structures, e.g., 406A, 406B) are formed, in accordance with various embodiments. Such a dummy gate structure can be formed based on one of the (gate structure) patterns discussed with respect to FIGS. 3A-B. The dummy gate structure can extend along a direction perpendicular to the lengthwise direction of the dielectric fin structure (and the stack). Further, the dummy gate structure may be formed shorter than the dielectric fin structure in one of various embodiments, and thus, the dummy gate structure, as formed, is cut (or otherwise separated) by the dielectric fin structure.

The dummy gate structure can be formed by depositing amorphous silicon (a-Si) over the stack. Other materials suitable for forming dummy gates (e.g., polysilicon) can be used while remaining within the scope of present disclosure. The a-Si is then planarized to a desired level. A hard mask is deposited over the planarized a-Si and patterned. The hard mask can be formed from a nitride or an oxide layer. An etching process (e.g., a reactive-ion etching (RIE) process) is applied to the a-Si to form the dummy gate structure. After forming the dummy gate structure, gate spacers may be formed to extend along sidewalls of the dummy gate structure. The gate spacers can be formed by a conformal deposition of a dielectric material (e.g., silicon oxide, silicon nitride, silicon oxynitride, SiBCN, SiOCN, SiOC, or any suitable combination of those materials) followed by a directional etch (e.g., RIE).

The method 500 proceeds to operation 510 in which inner spacers are formed by replacing end portions of each of the SiGe sacrificial nanostructures with a dielectric material, in accordance with various embodiments. Upon forming the dummy gate structure overlaying certain portions of the stack (e.g., the portions of the stack separated by the dielectric fin structure), the non-overlaid portions of the stack are removed. Next, respective end portions of each SiGe sacrificial nanostructure of the overlaid stack are removed. The inner spacers are formed by filling such recesses of each SiGe sacrificial nanostructure with a dielectric material by chemical vapor deposition (CVD), or by monolayer doping (MLD) of nitride followed by spacer RIE. A material of the inner spacers can be formed from the same or different material as the gate spacers described above. For example, the inner spacers can be formed of silicon nitride, silicoboron carbonitride, silicon carbonitride, silicon carbon oxynitride, or any other type of dielectric material (e.g., a dielectric material having a dielectric constant k of less than about 5).

The method 500 proceeds to operation 512 in which a number of epitaxial structures (e.g., 452, 454, 456, 458) are formed, in accordance with various embodiments. Upon forming the inner spacers, the epitaxial structures are formed using an epitaxial layer growth process on exposed ends of the Si nanostructures. In-situ doping (ISD) may be applied to form doped epitaxial structures, thereby creating the necessary junctions for a corresponding transistor (or sub-transistor). N-type and p-type FETs are formed by implanting different types of dopants to selected regions of the device to form the necessary junction(s). N-type devices can be formed by implanting arsenic (As) or phosphorous (P), and p-type devices can be formed by implanting boron (B). After forming the epitaxial structures, an inter-layer dielectric (e.g., silicon dioxide) is deposited to overlay the epitaxial structures.

The method 500 proceeds to operation 514 in which the dummy gate structures and the remaining SiGe sacrificial nanostructures are replaced with respective active gate structures (e.g., 406A, 406B, 408), in accordance with various embodiments. Subsequently to forming the inter-layer dielectric, the dummy gate structures are removed by an etching process, e.g., RIE or chemical oxide removal (COR). Next, the remaining SiGe sacrificial nanostructures are removed while keeping the Si channel nanostructure substantially intact by applying a selective etch (e.g., a hydrochloric acid (HCl)). After the removal of the SiGe sacrificial nanostructures, top and bottom surfaces and sidewalls of each of the Si channel nanostructures can be exposed, except for the sidewall in contact with the dielectric fin structure. Next, a number of active gate structures can be formed to wrap around each of the Si channel nanostructures, except for the sidewall contacting the dielectric fin structure. Each of the active gate structures includes at least a gate dielectric layer (e.g., a high-k dielectric layer) and a gate metal layer (e.g., a work function metal layer). Upon the active gate structures are formed, a number of programming/reading transistors of the disclosed anti-fuse cell can be formed.

The method 500 proceeds to operation 516 in which a number of interconnect structures are formed, in accordance with various embodiments. Upon forming the programming/reading transistors, a number of interconnect structures (e.g., VGs, VDs, MDs) are formed over the transistors. For example, a first VG is formed to connect a gate terminal of one of the programming transistors to a programming word line, second and third VGs are formed to respectively connect gate terminals of the reading transistors to a common reading word line, and an MD is formed to connect to source terminals of the reading transistors. The interconnect structure is formed of a metal material. The metal material can be selected from the group consisting of aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The interconnect structures can be formed by overlaying the workpiece with the above-listed metal material by, for example, chemical vapor deposition (CVD), physical vapor deposition (PVD), electroless plating, electroplating, or combinations thereof.

In one aspect of the present disclosure, a semiconductor device is disclosed. The semiconductor device includes a plurality of first nanostructures extending along a first lateral direction. The semiconductor device includes a plurality of second nanostructures extending along the first lateral direction. The semiconductor device includes a dielectric fin structure disposed immediately next to a first sidewall of each of the plurality of first nanostructures along a second lateral direction perpendicular to the first lateral direction. The semiconductor device includes a first gate structure wrapping around each of the plurality of first nanostructures except for the first sidewalls. The semiconductor device includes a second gate structure straddling the plurality of second nanostructures.

In another aspect of the present disclosure, a memory device is disclosed. The memory device includes a plurality of memory cells, each of which includes a first programming transistor and a first reading transistor coupled to each other in series, and a second programming transistor and a second reading transistor coupled to each other in series. A first channel structure of the first programming transistor has a first sidewall, and a second channel structure of the second programming transistor has a second sidewall facing the first sidewall. The first sidewall and second sidewall are each in contact with a dielectric fin structure.

In yet another aspect of the present disclosure, a method for fabricating a memory device is disclosed. The method includes forming a plurality of first nanostructures, a plurality of second nanostructures, a plurality of third nanostructures, and a plurality of fourth nanostructures. The method includes separating the plurality of first nanostructures and the plurality of second nanostructures with a dielectric fin structure. The dielectric structure also extends along the first lateral direction. The method includes forming a first gate structure wrapping around each of the first nanostructures except for a sidewall that is in contact with the dielectric fin structure. The method includes forming a second gate structure wrapping around each of the second nanostructures except for a sidewall that is in contact with the dielectric fin structure. The first and second gate structures extend along a second lateral direction perpendicular to the first lateral direction. The method includes forming a first interconnect structure coupled to one of the first gate structure or second gate structure.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a memory device, comprising:
forming a plurality of first nanostructures, a plurality of second nanostructures, a plurality of third nanostructures, and a plurality of fourth nanostructures;
separating the plurality of first nanostructures and the plurality of second nanostructures with a dielectric fin structure, wherein the dielectric structure also extends along the first lateral direction;
forming a first gate structure wrapping around each of the first nanostructures except for a sidewall that is in contact with the dielectric fin structure;
forming a second gate structure wrapping around each of the second nanostructures except for a sidewall that is in contact with the dielectric fin structure, wherein the first and second gate structures extend along a second lateral direction perpendicular to the first lateral direction; and
forming a first interconnect structure coupled to one of the first gate structure or second gate structure.

2. The method of claim 1, further comprising:
separating the plurality of third nanostructures and the plurality of fourth nanostructures with the dielectric fin structure;
forming a third gate structure wrapping around each of the third nanostructures except for a sidewall that is in contact with the dielectric fin structure;
forming a fourth gate structure wrapping around each of the fourth nanostructures except for a sidewall that is in contact with the dielectric fin structure, wherein the third and fourth gate structures extend along the second lateral direction; and
forming a second interconnect structure coupled to both of the third gate structure and fourth gate structure.

3. The method of claim 1, wherein the plurality of third nanostructures each extend from a corresponding one of the plurality of fourth nanostructures along the second lateral direction, the method further comprising:
forming a fifth gate structure wrapping around a combination of each of the third nanostructures and the corresponding fourth nanostructures; and
forming a third interconnect structure coupled to the fifth gate structure.

4. A method of fabricating a memory device, comprising:
forming a plurality of first nanostructures extending along a first lateral direction;
forming a plurality of second nanostructures extending along the first lateral direction;
forming a dielectric fin structure disposed immediately next to a first sidewall of each of the plurality of first nanostructures along a second lateral direction perpendicular to the first lateral direction;
forming a first gate structure wrapping around each of the plurality of first nanostructures except for the first sidewalls; and
forming a second gate structure straddling the plurality of second nanostructures.

5. The method of claim 4, wherein the dielectric fin structure extends along the first lateral direction.

6. The method of claim 4, wherein the first and second gate structures each are formed to extend along the second lateral direction.

7. The method of claim 4, wherein the dielectric fin structure is formed immediately next to a second sidewall of each of the plurality of second nanostructures along the second lateral direction.

8. The method of claim 7, wherein the second gate structure is formed to wrap around each of the plurality of second nanostructures except for the second sidewalls.

9. The method of claim 4, wherein the second gate structure is formed to wrap around each of the plurality of second nanostructures.

10. The method of claim 4, further comprising forming a plurality of third nanostructures extending along the first lateral direction.

11. The method of claim 10, wherein the plurality of third nanostructures each are formed to extend from a corresponding one of the plurality of second nanostructures along the second lateral direction, and wherein the second gate structure is formed to straddle the plurality of third nanostructures.

12. The method of claim 10, further comprising forming a third gate structure separated apart from the second gate structure with the dielectric fin structure but aligned with the second gate structure along the second lateral direction.

13. The method of claim 12, wherein the dielectric fin structure is formed immediately next to a third sidewall of each of the plurality of third nanostructures along the second lateral direction, and wherein the third gate structure is formed to wrap around each of the plurality of third nanostructures except for the third sidewalls.

14. The method of claim 4, wherein the plurality of first nanostructures and the first gate structure at least form, in part, a programming transistor of an anti-fuse memory cell, and the plurality of second nanostructures and the second gate structure at least form, in part, a reading transistor of the anti-fuse memory cell.

15. A method of fabricating a memory device, comprising:
forming a plurality of memory cells, each of which includes a first programming transistor and a first reading transistor coupled to each other in series, and a second programming transistor and a second reading transistor coupled to each other in series;
wherein a first channel structure of the first programming transistor is formed to have a first sidewall, and a second channel structure of the second programming transistor is formed to have a second sidewall facing the first sidewall; and
wherein the first sidewall and second sidewall are each formed in contact with a dielectric fin structure.

16. The method of claim 15, wherein a third channel structure of the first reading transistor is formed to have a third sidewall, and a fourth channel structure of the second reading transistor is formed to have a fourth sidewall facing the third sidewall, and wherein the third sidewall and fourth sidewall are each formed in contact with the dielectric fin structure.

17. The method of claim 15, wherein the first reading transistor and second reading transistor are formed to share a common fifth channel structure.

18. The method of claim 15, further comprising:
forming a plurality of programming word lines, one of which is operatively coupled to one of a gate of the first programming transistor or a gate of the second programming transistor; and
forming a plurality of reading word lines, one of which is operatively coupled to both of a gate of the first reading transistor and a gate of the second reading transistor.

19. The method of claim 15, further comprising:
forming a plurality of bit lines, one of which is operatively coupled to both of a source/drain of the first reading transistor and a source/drain of the second reading transistor.

20. The method of claim 15, wherein each of the first channel structure and second channel structure is formed to include a plurality of nanostructure vertically spaced apart from one another.
